(19) United States
(12) Patent Application Publication
(10) Pub. No.: US 2026/0123406 A1
(43) Pub. Date: Apr. 30, 2026

(54) SEMICONDUCTOR PACKAGE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Hsien-Wei CHEN, Hsinchu City (TW); Chieh-Lung LAI, Taichung City (TW); Meng-Liang LIN, Hsinchu (TW); Kathy Wei YAN, Hsinchu (TW)

(73) Assignee: TAIWAN SEMICONDUCTOR MANUFACTURING COMPANY, LTD., Hsinchu (TW)

(21) Appl. No.: 18/929,872

(22) Filed: Oct. 29, 2024

(51) Int. Cl. H01L 23/367; H01L 21/48; H01L 23/00; H01L 23/538; H01L 23/58; H01L 25/00; H01L 25/065

(52) U.S. Cl. CPC H10W 40/22; H10W 40/037; H10W 42/00; H10W 70/611; H10W 90/00; H10W 90/401; H10W 74/15; H10W 90/724; H10W 90/734

(57) ABSTRACT

A semiconductor package structure is provided. The semiconductor package structure includes a substrate, a redistribution structure disposed over the substrate, and a semiconductor die disposed over the redistribution structure. The redistribution structure includes a dielectric layer, a conductive feature formed in the dielectric layer, and a heat transfer feature formed in the dielectric layer and being electrically isolated from the conductive feature. The semiconductor die is electrically connected to the conductive feature. The semiconductor die partially overlaps the heat transfer feature from a top view.

### BACKGROUND

The semiconductor industry has experienced rapid grown due to continuous improvements in the integration density of a variety of electronic components (e.g., transistors, diodes, resistors, capacitors, etc.). For the most part, these improvements in integration density have come from successive reductions in minimum feature size, which allows more components to be integrated into a given area. As the demand for shrinking electronic devices has grown, a need for dissipating the heat generated by semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1I illustrate the cross-sectional views of intermediate stages in the formation of a semiconductor package structure, in accordance with some embodiments of the present disclosure.

FIG. 2 is a top view of the semiconductor package structure, in accordance with some embodiments.

FIG. 3 is a top view of a semiconductor package structure, in accordance with some embodiments.

FIG. 4 is a top view of a semiconductor package structure, in accordance with some embodiments.

FIG. 5 is a top view of a semiconductor package structure, in accordance with some embodiments.

FIG. 6 is a cross-sectional view of a semiconductor package structure, in accordance with some embodiments.

FIG. 7A is a cross-sectional view of a semiconductor package structure, in accordance with some embodiments.

FIG. 7B is a top view of the semiconductor package structure, in accordance with some embodiments.

FIG. 8A is a cross-sectional view of a semiconductor package structure, in accordance with some embodiments.

FIG. 8B is a top view of the semiconductor package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, the present disclosure may repeat reference numerals and/or letters in the various examples. This repetition is for the purpose of simplicity and clarity and does not in itself dictate a relationship between the various embodiments and/or configurations discussed.

The terms “about” and “substantially” typically mean+/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

Furthermore, the phrase “in a range between a first value and a second value” or “in a range from a first value to a second value” indicates that the range includes the first value, the second value, and other values between them.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

Embodiments of the present disclosure relates a semiconductor package structure having heat transfer features in the redistribution structure. Such feature allows heat generated by the chip in the semiconductor package structure not only can be dissipated upwardly through the heat sink, but also dissipated downwardly through the redistribution structure and the substrate below the redistribution structure.

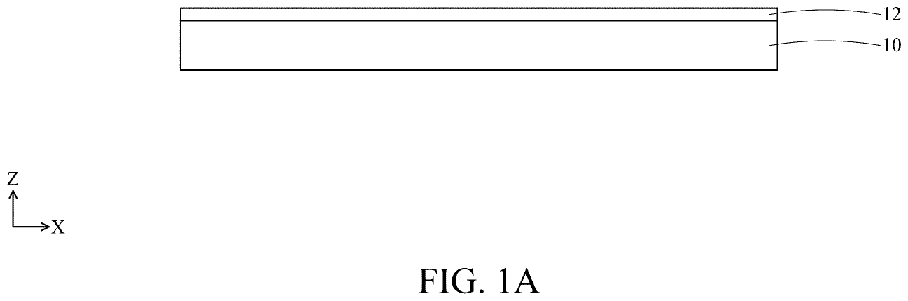

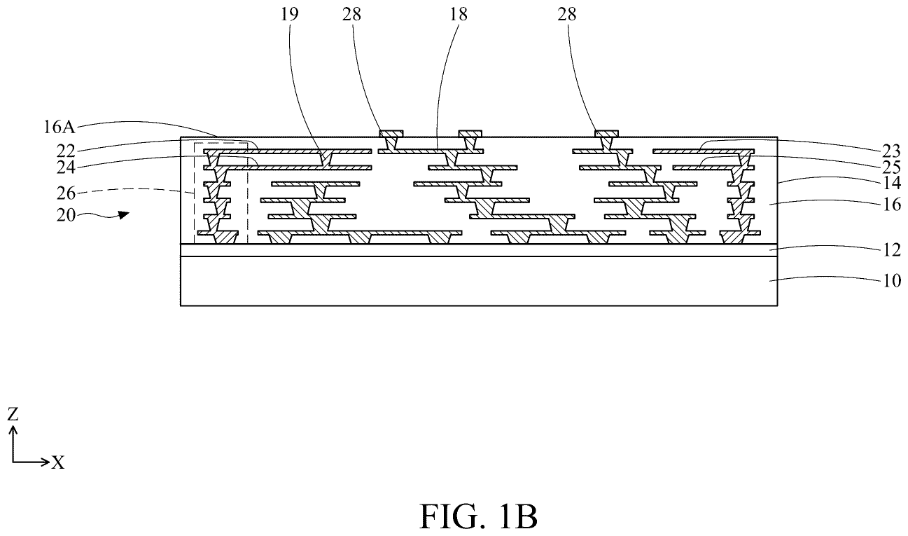

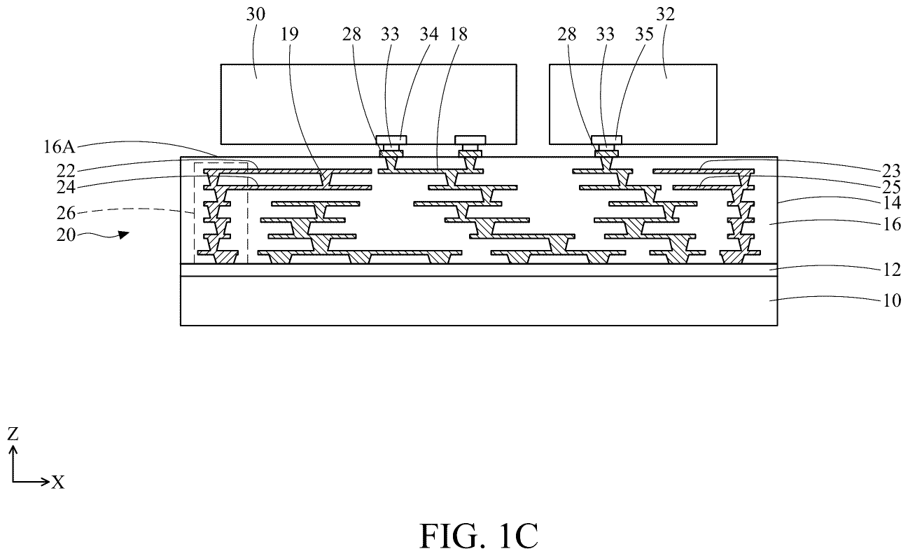

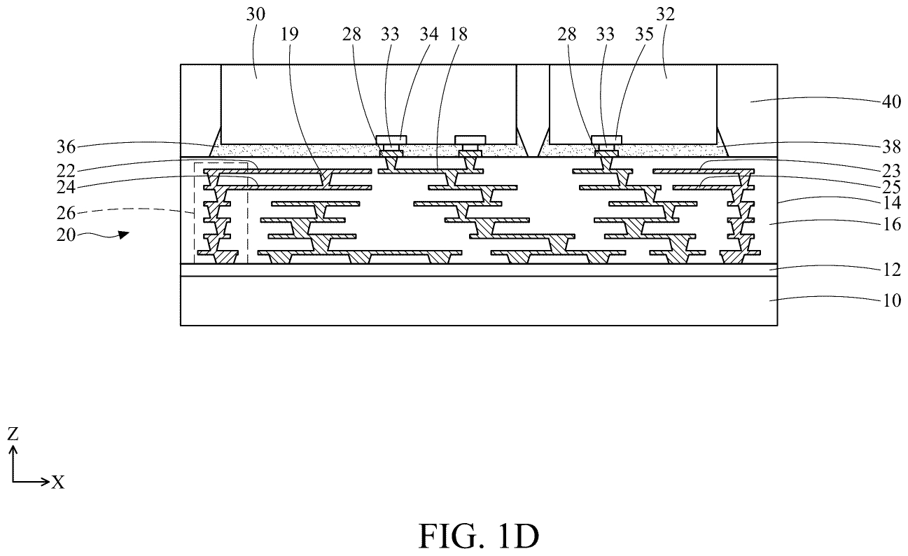

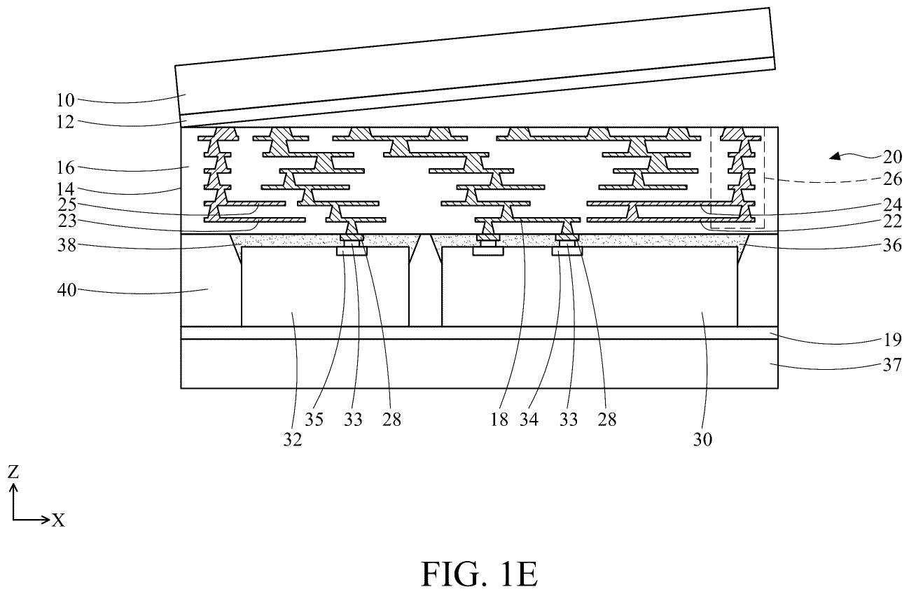

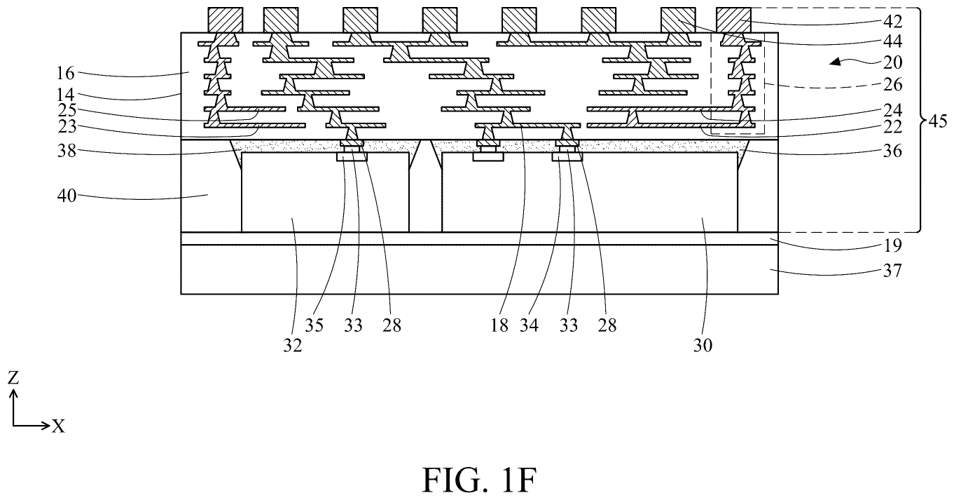

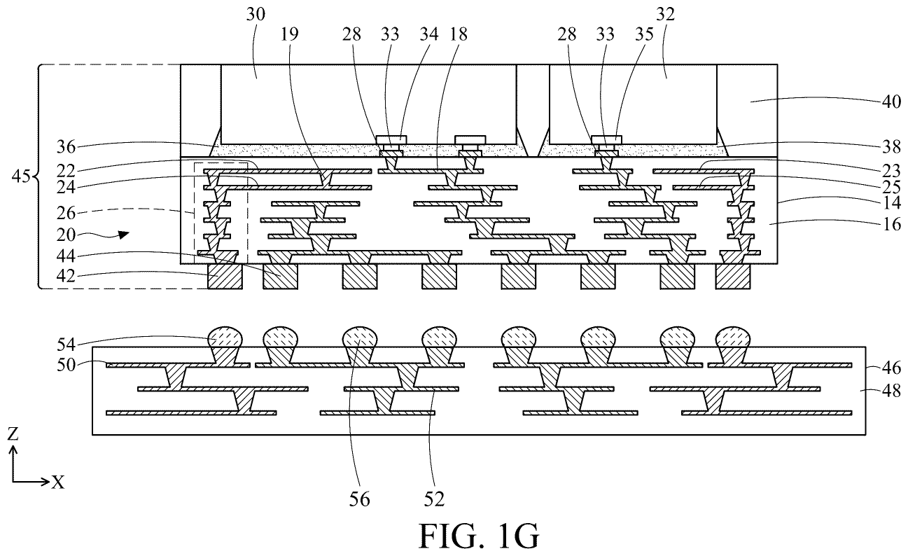

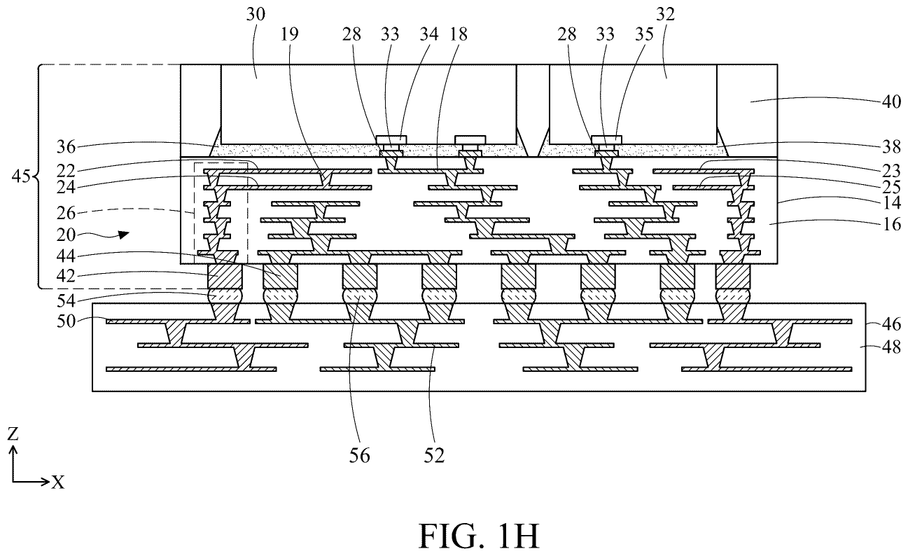

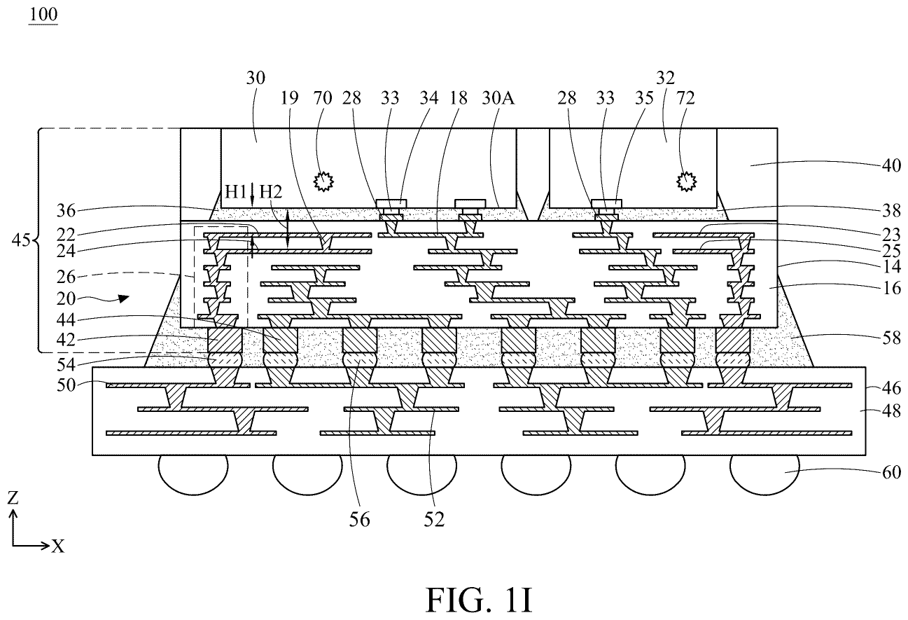

FIG. 1A to FIG. 1I illustrate the cross-sectional views of intermediate stages in the formation of a semiconductor package structure, in accordance with some embodiments of the present disclosure. FIG. 1A illustrates a carrier 10 and a release film 12 on the carrier 10. In some embodiments, the carrier 10 may be a glass carrier, a silicon wafer, an organic carrier, or the like. The carrier 10 may have a round top-view shape in accordance with some embodiments. In some embodiments, the release film 12 may be formed of a polymer-based material and/or an epoxy-based thermal-release material (such as a Light-To-Heat-Conversion (LTHC) material), which is capable of being decomposed under radiation such as a laser beam, so that the carrier 10 may be de-bonded from the overlying structures that will be formed in subsequent processes. In accordance with some embodiments of the present disclosure, the release film 12 is applied on the carrier 10 through coating.

Referring to FIG. 1B, a redistribution structure 14, which includes a plurality of dielectric layers 16, a plurality of conductive features 18, and a plurality of heat transfer features 20, is provided over the release film 12. In some embodiments, the conductive features 18 may be used for conducting electricity, and the heat transfer features 20 may be used for transferring heat. For example, semiconductor dies 30 and 32 (shown in FIG. 1C) may be disposed over the redistribution structure 14, the conductive features 18 may electrically connect the semiconductor dies 30 and 32 to other devices, and the heat transfer features 20 may be used for dissipating the heat generated by the semiconductor dies 30 and 32.

Further referring to FIG. 1B, the conductive features 18 and heat transfer features 20 (including a via 19, heat transfer layers 22, 23, 24, 25 and a sealing ring 26) are formed in the dielectric layers 16. It should be noted that the heat transfer features 20 are electrically isolated from the conductive features 18. In some embodiments, at least one of the heat transfer layers 22 and 24 is connected to the sealing ring 26, and at least one of the heat transfer layers 23 and 25 is connected to the sealing ring 26. In some embodiments, the sealing ring 26 surrounds the conductive features 18 and the heat transfer layers 22, 23, 24, 25. In some embodiments, the heat transfer layers 22 and 24 are connected by the via 19, and the via 19 is separated from the sealing ring 26 and surrounded by the sealing ring 26.

In some embodiments, the dielectric layers 16 are made of one or more suitable dielectric materials such as an oxide (e.g., silicon oxide), a nitride (e.g., silicon nitride), a polymer material, a polyimide material, a low-k dielectric material, a molding material (e.g., an EMC or the like), another dielectric material, or a combination thereof. The dielectric layers 16 may be formed by a process such as spin-coating, lamination, CVD, the like, or a combination thereof. However, any suitable dielectric materials and any suitable processes may be used.

In some embodiments, the conductive features 18, the via 19, the heat transfer layers 22, 23, 24, 25 and the sealing ring 26 are made of a conductive material such as copper, titanium, tungsten, aluminum, another metal, or a combination thereof. The conductive material may be formed through a deposition process such as electroplating, electroless plating, or the like. However, while the material and methods discussed are suitable to form the conductive material, these are merely examples. Any other suitable materials or any other suitable processes of formation, such as CVD or PVD, may also be used to form the redistribution layer 14.

In accordance with some embodiments, the formation of the conductive features 18 and the heat transfer features 20 may further include repeatedly depositing the dielectric layers 16, patterning the dielectric layers 16, and forming conductive materials over the dielectric layers 16. The conductive materials may be seen as the conductive features 18, the via 19, the heat transfer layers 22, 23, 24, 25 and the sealing ring 26. In addition, metal seed layers (not shown) may be formed before forming the conductive materials.

In some embodiments, the conductive features 18 and the heat transfer features 20 are formed by same processes, such as using same patterned masks during the exposure process. Therefore, conductive features 18 and the heat transfer features 20 are formed at the same time, such as a layer of the conductive features 18 and the heat transfer layer 22 are formed at the same time, and another layer of the conductive features 18 and the heat transfer layer 24 are formed at the same time.

After the formation of the redistribution structure 14, the conductive features 18 are partially exposed from the dielectric layers 16, and the heat transfer features 20 is embedded in the dielectric layers 16, in accordance with some embodiments. In some embodiments, the conductive features 18 have conductive vias exposed from the top surface 16A of the dielectric layers 16, and the heat transfer features 20 are not exposed from the top surface 16A.

Afterwards, conductive features 28 may be formed over a top surface 16A of the dielectric layers 16 and connected to the conductive features 18, in accordance with some embodiments. The conductive features 28 are separated from the heat transfer features 20 by the dielectric layers 16. The conductive features 28 may be formed of or include micro-bumps, metal pads, metal pillars, Under-Bump-Metallurgies (UBMs), solder regions, and/or the like. The formation of conductive features 28 may also be similar to the formation of the conductive features 18 and the heat transfer features 20, which formation process includes patterning the top dielectric layer to expose the underlying conductive features 18, forming a metal seed layer, forming a patterned plating mask, performing one or a plurality of plating processes to form the conductive features 28, removing the plating mask, and etching the metal seed layer. The conductive features 28 may also include copper, aluminum, cobalt, nickel, gold, silver, tungsten, alloys thereof, and/or multi-layers thereof. When the conductive features 28 include solder regions, the solder regions may be plated using the same plating mask used for plating the underlying non-solder portions, followed by a reflow process to round the surfaces of the solder regions. The solder regions may include Sn and Ag, and may or may not include gold.

In accordance with alternative embodiments, the dielectric materials in the redistribution structure 14 may comprise a ceramic material, a resin (e.g. epoxy-based resin, polyimide-based resin), prepreg, glass, or the like. Throughout the description, the dielectric layers 16, the conductive features 18, the heat transfer features 20, and the conductive features 28 may be collectively called as the redistribution structure 14.

FIG. 1C illustrates the bonding of semiconductor dies 30 and 32 to the redistribution structure 14. The conductive features 34 and 35 are the surface features of the semiconductor dies 30 and 32, respectively. The conductive features 34 and 35 may be bonded to conductive features 28 through conductive features 33 in accordance with some embodiments. The conductive features 34 and 35 overlaps the semiconductor dies 30 and 32 in a direction that is perpendicular to the top surface 16A of the dielectric layers 16, such as the Z direction. The conductive features 34 and 35 may be UBMs, metal pillars, bond pads, or the like. In accordance with alternative embodiments, the conductive features 34 and 35 are metal pillars, and are bonded to conductive features 28 through direct metal-to-metal bonding, with no solder regions therebetween.

In some embodiments, the semiconductor dies 30 and 32 are positioned right above the heat transfer features 20 to dissipate the heat generated from the semiconductor dies 30 and 32 by the heat transfer features 20. In particular, the semiconductor die 30 is located right above the heat transfer layers 22 and 24 and the via 19, and the semiconductor die 32 is located above the heat transfer layers 23 and 25. In some embodiments, the semiconductor dies 30 and 32 do not locate direct above the sealing ring 26.

In accordance with some embodiments, the semiconductor dies 30 and 32 may include a plurality of groups of semiconductor dies, with the groups being identical to each other. Each of the groups may be a single-component group or a multi-component group, in accordance with some embodiments. For example, FIG. 1C illustrates an example in which each group includes two semiconductor dies 30 and 32. In accordance with some embodiments, semiconductor dies 30 and 32 include a logic die, which may be a Central Processing Unit (CPU) die, a Graphic Processing Unit (GPU) die, a mobile application die, a Micro Control Unit (MCU) die, an input-output (IO) die, a BaseBand (BB) die, an Application processor (AP) die, or the like. The semiconductor dies 30 and 32 may also include memory dies such as Dynamic Random-Access Memory (DRAM) dies, Static Random-Access Memory (SRAM) dies, or the like. The memory dies may be discrete memory dies, or may be in the form of a die stack that includes a plurality of stacked memory dies. The semiconductor dies 30 and 32 may also include System-on-Chip (SOC) dies. The semiconductor dies 30 and 32 may be discrete device dies or packages.

Referring to FIG. 1D, an underfill material 36 is dispensed into the gaps between the semiconductor dies 30 and 32 and the redistribution structure 14. The underfill material 36 may also be dispensed between neighboring semiconductor dies 30 and 32 that are in the same group of semiconductor dies. In accordance with some embodiments, the underfill material 36 includes a base material and filler particles mixed in the base material. The base material may be a resin, an epoxy, and/or a polymer. Some example base materials include epoxy-amine, epoxy anhydride, epoxy phenol, or the like, or combinations thereof. The filler particles may be formed of a dielectric material, and may include silica, alumina, boron nitride, or the like. The filler particles may have spherical shapes. The underfill material 36 is dispensed in a flowable form, and is then cured. In accordance with alternative embodiments, the underfill material 36 is formed of a non-conductive film, which is placed on the redistribution structure 14 first, and the semiconductor dies 30 and 32 are pressed against redistribution structure 14, so that the conductive features 33 in the semiconductor dies 30 and 32 penetrate through the non-conductive film to contact the conductive features 28.

Next, semiconductor dies 30 and 32 are encapsulated in an encapsulant 40. The respective process is illustrated as process 208 in the process flow 200 as shown in FIG. 21. The encapsulant 40 may be a molding compound, a molding underfill, an epoxy, and/or a resin. The encapsulant 40 may include a base material, and a filler in the base material. The base material may include a polymer material, which may be or may comprise a plastic, an epoxy resin (such as Epoxy Cresol Novolac (ECN), biphenyl epoxy resin, or a multifunctional liquid epoxy resin), polyimide, polyethylene terephthalate (PET), polyvinyl chloride (PVC), polymethylmethacrylate (PMMA), or the like. The filler may include titanium dioxide, carbon black, calcium carbonate, silica, fiber, clay, ceramic, inorganic particles, and or the like, and may be in the form of filler particles.

A planarization process such as a Chemical Mechanical Polish (CMP) process or a mechanical grinding process is then performed to polish the encapsulant 40. The semiconductor dies 30 and 32 may be exposed as a result of the planarization process. For example, when the semiconductor dies 30 and 32 include semiconductor substrates, the semiconductor substrates may be exposed.

FIG. 1E illustrates a carrier switch process. First, a carrier 37 is adhered to the semiconductor dies 30, 32 and the encapsulant 40. A release film 39, which may also include a thermal release film such as an LTHC, is used to adhere carrier 37 to the semiconductor dies 30, 32 and the encapsulant 40. The carrier 10 is then de-bonded, for example, by projecting UV light or a laser beam, which penetrates through the carrier 10, on the release film 12. The release film 12 decomposes under the heat of the UV light or the laser beam. The remained structure may then be de-bonded from the carrier 10.

FIG. 1F illustrates the formation of heat transfer features 42 and conductive features 44. In accordance with some embodiments, the formation process includes placing solder balls on the conductive features 18 and the heat transfer features 20, and performing a reflow process. The formation process may also include depositing a metal seed layer, forming a patterned plating mask, and plating the heat transfer features 42 and the conductive features 44 on the metal posts. The plating mask is then removed, followed by the etching of the metal seed layer. A reflow process is then performed to reflow the heat transfer features 42 and the conductive features 44. The structure above the release film 39 may be collectively referred as a package 45. It should be noted that the heat transfer features 42 directly connects to the sealing ring 26 and are electrically isolated from the conductive features 44 to prevent short circuit, in accordance with some embodiments of the present disclosure.

FIG. 1G and FIG. 1H illustrate the alignment and the bonding of the package 45 on a substrate 46. Referring to FIG. 1G, the package 45 is aligned to the substrate 46. In accordance with some embodiments, the substrate 46 may be or may include a package substrate (cored or core-less), an interposer, a package including device dies therein, a device die, a printed circuit board, or the like. In some embodiments, the substrate 46 may include dielectric layers 48 and heat transfer features 50 and conductive features 52 embedded in the dielectric layers 48. Afterwards, heat transfer features 54 and conductive features 56 may be, or may not be, respectively pre-formed on the heat transfer features 50 and conductive features 52 of the substrate 46. The heat transfer features 50 are electrically isolated from the conductive features 52, and the heat transfer features 54 are electrically isolated from the conductive features 56 to prevent short circuit from occurring between the features, in accordance with some embodiments.

Next, the package 45 is placed on the substrate 46, in accordance with some embodiments. A reflow process is then performed, so that the package 45 is bonded to substrate 46, as shown in FIG. 1H. The heat transfer features 42 are bonded to the heat transfer features 54, and the conductive features 44 are bonded to the conductive features 56 to bond the redistribution structure 14 to the substrate 46. It should be noted that the heat transfer features 54 and the conductive features 56 are electrically isolated from each other.

Referring to FIG. 1I, an underfill material 58 is dispensed into the gap between the package 45 and the substrate 46. In accordance with some embodiments, the underfill material 58 includes a base material and filler particles mixed in the base material. The base material may be a resin, an epoxy, and/or a polymer. Some example base materials include epoxy-amine, epoxy anhydride, epoxy phenol, or the like, or combinations thereof. The filler particles may be formed of a dielectric material, and may include silica, alumina, boron nitride, or the like. The filler particles may have spherical shapes. The underfill material 58 is dispensed in a flowable form, and is then cured.

FIG. 1I further illustrates the formation of conductive features 60, which are electrically connected to the conductive features 52 in the substrate 46, in accordance with some embodiments. A semiconductor package structure 100 is thus formed. In accordance with some embodiments, the formation of the conductive features 60 includes etching a bottom dielectric layer in the substrate 46 to reveal the metal pads of the conductive features 52, and forming conductive features 60 connected to the metal pads. In accordance with some embodiments, the conductive features 60 include solder regions, which may be formed by placing solder balls on the metal pads, and then performing a reflow process.

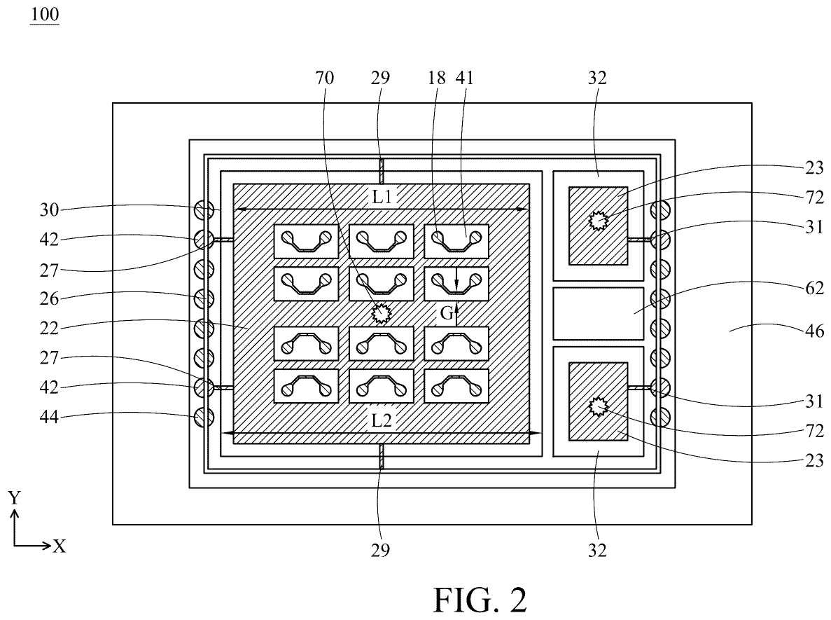

FIG. 2 is a top view of the semiconductor package structure 100, in accordance with some embodiments. As shown in FIG. 1I and FIG. 2, since the semiconductor dies 30 and 32 are heat sources, the semiconductor dies 30 and 32 may respectively have hot spots 70 and 72 located at specific positions of the semiconductor dies 30 and 32, in accordance with some embodiments. The heat transfer layers 22, 23, 24, and 25 may be designed to be right below the hot spots 70 and 72. Therefore, heat generated from the semiconductor dies 30 and 32 may be transferred to the heat transfer layers 22, 23, 24, and 25. Afterwards, the heat transfer layers 22 and 24 may be connected to the sealing ring 26 by heat transfer units 27 and 29, and the heat transfer layers 23 and 25 may be connected to the sealing ring 26 by heat transfer units 31. In some embodiments, the heat transfer units 27, 29, and 31 may be metal wires, and may be formed by identical processes of the conductive features 18 and the heat transfer features 20. Afterwards, the sealing ring 26 is sequentially connected to the heat transfer features 42, 54, and 50. Therefore, heat generated from the semiconductor dies 30 and 32 may be dissipated to the substrate 46 to enhance downstream side heat dissipation. In some embodiments, the sealing ring 26 overlaps the heat transfer features 42 from a top view to reduce the heat transfer path.

In some embodiments, as shown in FIG. 1I, a first distance H1 between the uppermost heat transfer layer 22 and a bottom surface 30A of the semiconductor die 30 is between about 20 μm and about 30 μm to enhance heat transfer. In some embodiments, the second distance H1 is less than a second distance H2 between the heat transfer layer 24 and the bottom surface 30A of the semiconductor die 30.

In some embodiments, as shown in FIG. 2, the conductive features 18 are surrounded by empty zones 41 formed in the heat transfer layers 22 and 24. Empty zones 41 are regions that are free of conductive material, such as filled by the dielectric material of the dielectric layers 16, to prevent short circuit between the conductive features 18 and the heat transfer layers 22 and 24. A minimum gap G between the conductive features 18 and the heat transfer features 20 (such as the heat transfer layer 22) in a horizontal direction (a direction in the XY plane perpendicular to the Z direction, such as in the Y direction) is greater than about 10 μm to ensure the electrical isolation between the conductive features 18 and the heat transfer features 20. In some embodiments, as shown in FIG. 2, the size L1 of the heat transfer layer 22 is less than the size L2 of the semiconductor die 30 from a top view. In some embodiments, the heat transfer layer 22 is within the boundaries of the semiconductor die 30. In some embodiments, the size L1 is less than about 30 μm, such as between about 10 μm and about 30 μm.

Optionally, a dummy semiconductor device 62 is disposed between the semiconductor dies 32 (such as attached to the dielectric layers 16, in accordance with some embodiments. Although one dummy semiconductor device 62 is shown, any desired quantity of dummy semiconductor device 62 may be attached to the dielectric layers 16). The dummy semiconductor device 62 are substantially free of any active or passive devices. In some embodiments, the dummy semiconductor device 62 may be attached to the dielectric layers 16 by placing the dummy semiconductor device 62 on the dielectric layers 16, and then bonding the dummy semiconductor device 62 to the dielectric layers 16. The dummy semiconductor device 62 may be placed by, e.g., a pick-and-place process. The bonding process may include fusion bonding, dielectric bonding, or the like. For example, the dummy semiconductor device 62 may be directly bonded to the dielectric layers 16 through dielectric-to-dielectric bonding, without using any adhesive material (e.g., die attach film). The bonding may include a pre-bonding and an annealing to the dielectric layers 16. In some embodiments, the dummy semiconductor device 62 are bonded to the dielectric layers 16 by the same bonding process as the semiconductor dies 30 or 32.

Including the dummy semiconductor device 62 in the package can help reduce the size of gaps between the semiconductor dies 32, thereby improving structural reliability of the package. In some embodiments, no heat transfer feature is below the dummy semiconductor device 62 from a top view since the dummy semiconductor device 62 does not generate heat. In other words, the projection of the heat transfer layer 22 on the substrate 46 is separated from the projection of the dummy semiconductor device 62 on the substrate 46 to reduce the size of the heat transfer layer 22.

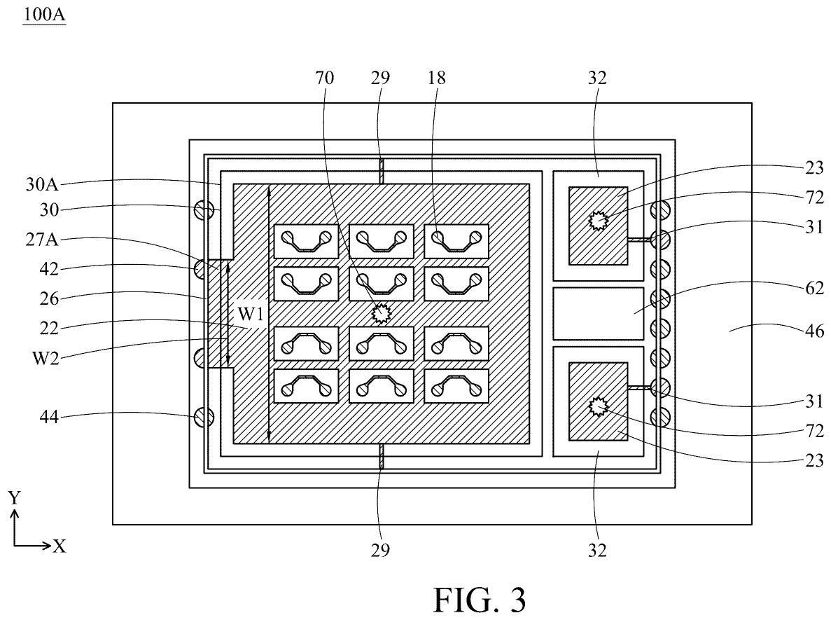

FIG. 3 is a top view of a semiconductor package structure 100A, in accordance with some embodiments. As shown in FIG. 3, the semiconductor package structure 100A has a heat transfer unit 27A connected to the sealing ring 26, in accordance with some embodiments. In some embodiments, the heat transfer unit 27A partially overlaps a plurality of heat transfer features 42 from a top view. In some embodiments, the heat transfer layer 22 has a width W1 along the Y axis, the heat transfer unit 27A has a width W2 along the Y axis, and the width W2 is less than the width W1. For example, the width W2 may be less than ⅓ of the width W1. Since the heat transfer unit 27A overlaps a plurality of heat transfer features 42 from a top view, the heat transfer efficiency may be increased to further dissipate the heat generated from the semiconductor die 30. Similar configuration may be applied to the semiconductor die 32 as well.

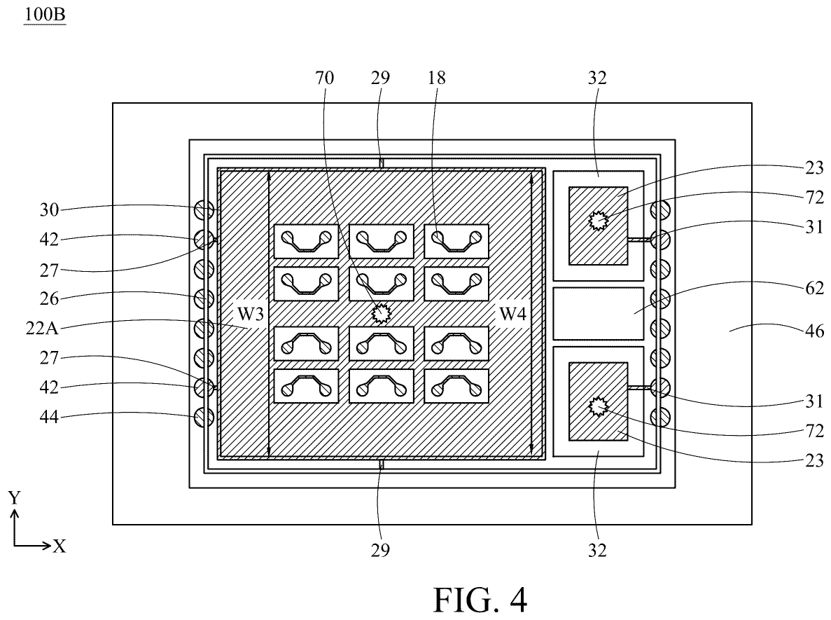

FIG. 4 is a top view of a semiconductor package structure 100B, in accordance with some embodiments. As shown in FIG. 4, the semiconductor package structure 100B has a heat transfer layer 22A extending beyond the semiconductor die 30. In some embodiments, a width W3 of the heat transfer layer 22A is greater than a width W4 of the semiconductor die 30. Therefore, heat dissipation efficiency may be further enhanced.

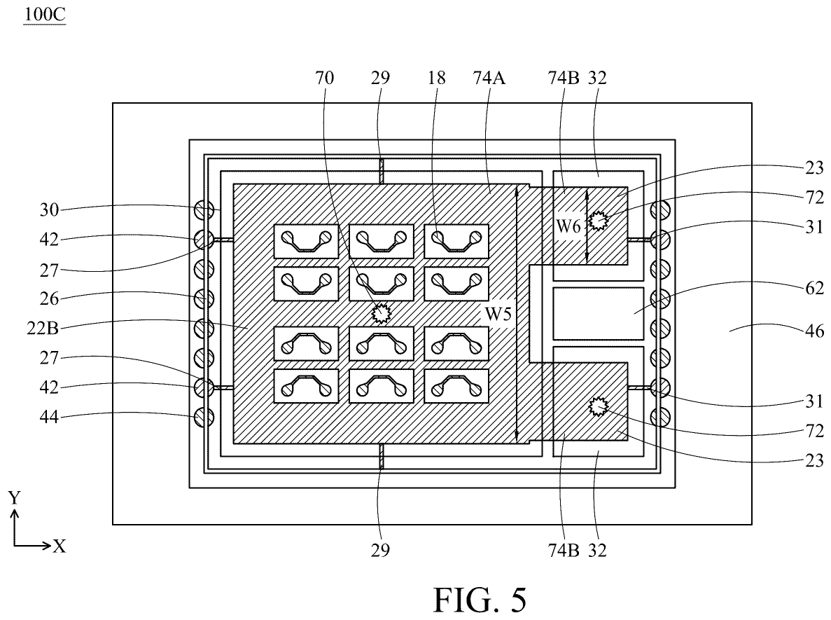

FIG. 5 is a top view of a semiconductor package structure 100C, in accordance with some embodiments. As shown in FIG. 5, the semiconductor package structure 100C has a heat transfer layer 22B continuously extending below the semiconductor die 30 and the semiconductor dies 32. For example, the heat transfer layer 22B has a portion 74A below the semiconductor die 30, and portions 74B below the semiconductor dies 32. The portions 74B connect to a side of the portion 74A. In some embodiments, the portion 74A has a width W5 in the Y axis, the portion 74B has a width W6 in the Y axis, and the width W5 and the width W6 may be different. For example, the width W5 may be greater than the width W6. In some embodiments, a part of the portion 74B does not overlap the semiconductor dies 30 or 32 from a top view. In some embodiments, the heat transfer layer 22B does not extend below the dummy semiconductor device 62. In some embodiments, the dummy semiconductor device 62 is between the portions 74B from a top view.

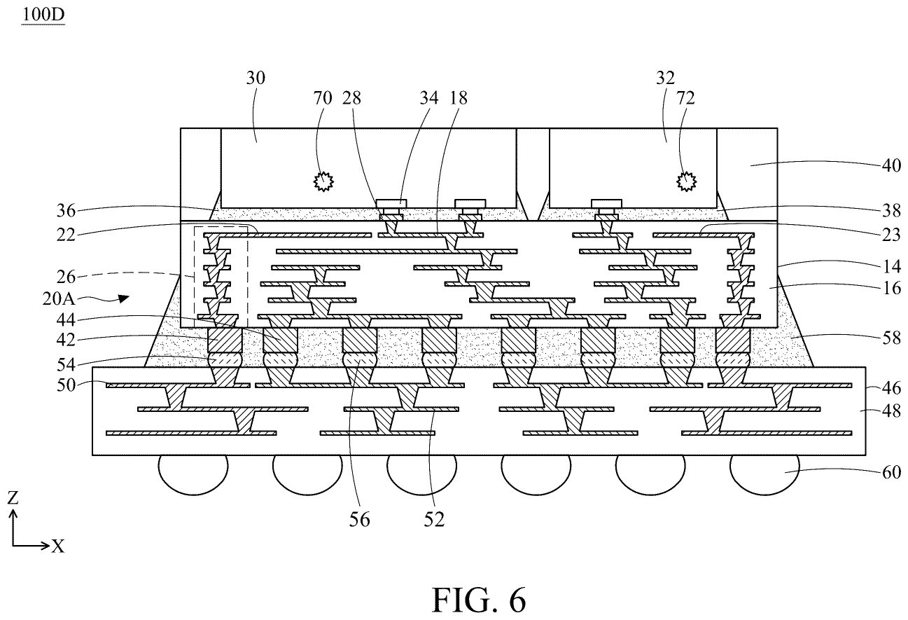

FIG. 6 is a cross-sectional view of a semiconductor package structure 100D, in accordance with some embodiments. As shown in FIG. 6, the semiconductor package structure 100D has a heat transfer feature 20A in the redistribution structure 14, in accordance with some embodiments. The heat transfer feature 20A includes a single layer of heat transfer layer 22 below the semiconductor die 30 and a single layer of heat transfer layer 23 below the semiconductor die 32. Some of the conductive features 18 may extend below the heat transfer layer 22 or 23, sandwiching the heat transfer layer 22 or 23 between the semiconductor dies 30 or 32 and the conductive features 18. As a result, this configuration gives more space to the conductive features 18 for electrical connection.

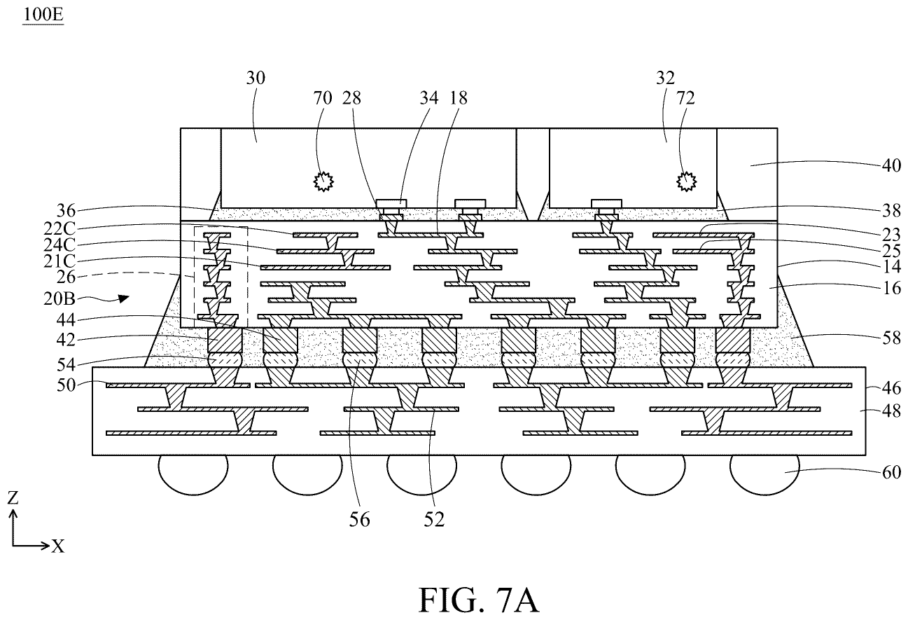

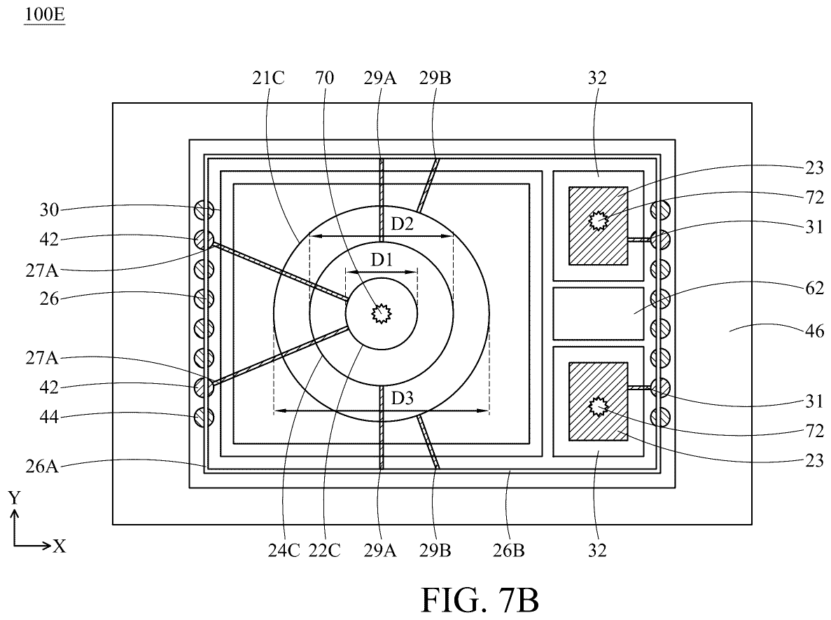

FIG. 7A is a cross-sectional view of a semiconductor package structure 100E, in accordance with some embodiments. FIG. 7B is a top view of the semiconductor package structure 100E, in accordance with some embodiments. As shown in FIG. 7A and FIG. 7B, the semiconductor package structure 100E has a heat transfer feature 20B, and the heat transfer feature 20B has heat transfer layers 22C, 24C, and 21C, in accordance with some embodiments. The heat transfer layers 22C, 24C, and 21C may have circular shapes and may overlap each other from a top view. In some embodiments, diameters of the heat transfer layers 22C, 24C, and 21C may gradually increase along the −Z direction. For example, the heat transfer layers 22C, 24C, and 21C has diameters D1, D2, and D3, respectively, and D1<D2<D3. In some embodiments, the heat transfer layers 22C, 24C, and 21C are below the hot spot 70 of the semiconductor die 30. Therefore, heat generated from the hot spot 70 of the semiconductor die 30 may be gradually dissipated by the increased size of the heat transfer layers 22C, 24C, and 21C.

In some embodiments, as shown in FIG. 7B, the semiconductor package structure 100E may further include heat transfer units 27A, 29A, and 29B. In some embodiments, the heat transfer units 27A connect the heat transfer layer 22C to the sealing ring 26, the heat transfer units 29A connect the heat transfer layer 24C to the sealing ring 26, and the heat transfer units 29B connect the heat transfer layer 21C to the sealing ring 26. In some embodiments, the heat transfer units 27A, 29A, and 29B extend in different directions. In some embodiments, the heat transfer units 27A, 29A, and 29B connect to an identical side or different sides of the sealing ring 26. For example, the heat transfer units 27A connect to a side 26A of the sealing ring 26, and the heat transfer units 29A and 29B connect to another side 26B of the sealing ring 26 to dissipate heat at different locations, which further enhances the heat dissipation of the semiconductor package structure 100E, in accordance with some embodiments of the present disclosure.

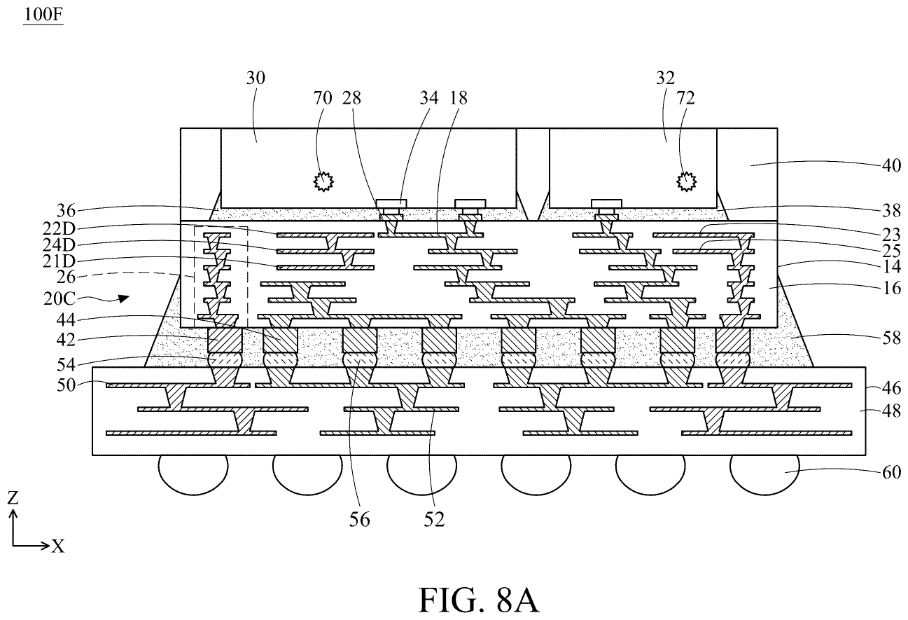

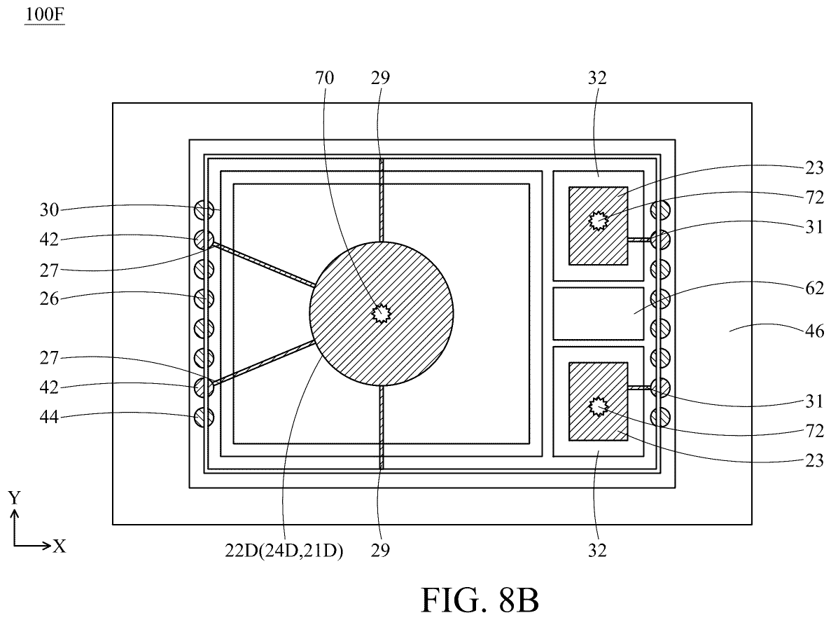

FIG. 8A is a cross-sectional view of a semiconductor package structure 100F, in accordance with some embodiments. FIG. 8B is a top view of the semiconductor package structure 100F, in accordance with some embodiments. As shown in FIG. 8A and FIG. 8B, the semiconductor package structure 100F has a heat transfer feature 20C, and the heat transfer feature 20C has heat transfer layers 22D, 24D, and 21D. In some embodiments, diameters of the heat transfer layers 22D, 24D, and 21D may be substantially identical, and sidewalls of the heat transfer layers 22D, 24D, and 21D may align with each other.

In summary, semiconductor package structures having a heat transfer layer in the redistribution structure under the semiconductor die are provided in some embodiments of the present disclosure. The heat transfer layer is then connected to the sealing ring in the redistribution structure and the heat transfer feature between the redistribution structure and a substrate, in accordance with some embodiments. Therefore, heat generated by the semiconductor die may be dissipated through the route under the semiconductor die to the substrate, thereby enhancing the heat dissipation of the entire package structure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A semiconductor package structure is provided in some embodiments of the present disclosure. The semiconductor package structure includes a substrate, a redistribution structure disposed over the substrate, and a semiconductor die disposed over the redistribution structure. The redistribution structure includes a dielectric layer, a conductive feature formed in the dielectric layer, and a heat transfer feature formed in the dielectric layer and being electrically isolated from the conductive feature. The semiconductor die is electrically connected to the conductive feature. The semiconductor die partially overlaps the heat transfer feature from a top view.

A semiconductor package structure is provided in some embodiments of the present disclosure. The semiconductor package structure includes a substrate, a redistribution structure disposed over the substrate, and a first semiconductor die disposed over the redistribution structure. The redistribution structure includes a first dielectric layer, a first conductive feature formed in the first dielectric layer, a heat transfer layer formed in the first dielectric layer and being electrically isolated from the first conductive feature, and a sealing ring formed in the first dielectric layer and connected to the heat transfer layer. The first semiconductor die is electrically connected to the first conductive feature. The first semiconductor die is surrounded by the sealing ring from a top view.

A method for forming a semiconductor package structure is provided in some embodiments of the present disclosure. The method includes forming a first conductive feature and a heat transfer feature in dielectric layers, and bonding a die over the redistribution structure. The first conductive feature and the heat transfer feature are electrically isolated from each other. The die is electrically connected to the first conductive feature, and the heat transfer feature overlaps the die in a direction that is perpendicular to a top surface of the dielectric layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a substrate;
a redistribution structure disposed over the substrate, comprising:
a dielectric layer;
a conductive feature formed in the dielectric layer; and
a heat transfer feature formed in the dielectric layer and being electrically isolated from the conductive feature; and
a semiconductor die disposed over the redistribution structure and electrically connected to the conductive feature, wherein the semiconductor die partially overlaps the heat transfer feature from a top view.

2. The semiconductor package structure as claimed in claim 1, wherein the heat transfer feature comprises:
a first heat transfer layer overlapping the semiconductor die from the top view;
a sealing ring surrounding the semiconductor die from the top view; and
a heat transfer unit connecting the first heat transfer layer and the sealing ring.

3. The semiconductor package structure as claimed in claim 2, wherein a width of the heat transfer unit is less than ⅓ of a width of the first heat transfer layer.

4. The semiconductor package structure as claimed in claim 2, wherein the heat transfer feature further comprises a second heat transfer layer overlapping the semiconductor die and the first heat transfer layer from the top view.

5. The semiconductor package structure as claimed in claim 4, wherein the first heat transfer layer and the second heat transfer layer have different sizes from the top view.

6. The semiconductor package structure as claimed in claim 5, wherein a first distance between the first heat transfer layer and the semiconductor die is less than a second distance between the second heat transfer layer and the semiconductor die, and the size of the first heat transfer layer is less than the size of the second heat transfer layer.

7. The semiconductor package structure as claimed in claim 2, wherein a size of the first heat transfer layer is greater than a size of the semiconductor die.

8. A semiconductor package structure, comprising:
a substrate;
a redistribution structure disposed over the substrate, comprising:
a first dielectric layer;
a first conductive feature formed in the first dielectric layer;
a heat transfer layer formed in the first dielectric layer and being electrically isolated from the first conductive feature; and
a sealing ring formed in the first dielectric layer and connected to the heat transfer layer; and
a first semiconductor die disposed over the redistribution structure and electrically connected to the first conductive feature, wherein the first semiconductor die is surrounded by the sealing ring from a top view.

9. The semiconductor package structure as claimed in claim 8, further comprising a first heat transfer feature between the substrate and the redistribution structure, wherein the first heat transfer feature overlaps the sealing ring from the top view.

10. The semiconductor package structure as claimed in claim 9, wherein the substrate comprises:
a second dielectric layer;
a second heat transfer feature embedded in the second dielectric layer; and
a second conductive feature embedded in the second dielectric layer and electrically isolated from the second heat transfer feature,
wherein the first heat transfer feature connects to the second heat transfer feature, and the first conductive feature is electrically connected to the second conductive feature.

11. The semiconductor package structure as claimed in claim 8, further comprising a second semiconductor die disposed over the redistribution structure and electrically connected to the first conductive feature, wherein the heat transfer layer continuously extends below the first semiconductor die and the second semiconductor die.

12. The semiconductor package structure as claimed in claim 11, wherein the heat transfer layer comprises a first portion below the first semiconductor die and a second portion below the second semiconductor die, and a first width of the first portion is different from a second width of the second portion.

13. The semiconductor package structure as claimed in claim 11, wherein the heat transfer layer is sandwiched between the first conductive feature and the first semiconductor die.

14. The semiconductor package structure as claimed in claim 8, further comprising a dummy semiconductor device disposed over the redistribution structure, wherein a projection of the heat transfer layer on the substrate is separated from a projection of the dummy semiconductor device on the substrate.

15. A method for forming a semiconductor package structure, comprising:
forming a first conductive feature and a heat transfer feature in dielectric layers to form a redistribution structure, wherein the first conductive feature and the heat transfer feature are electrically isolated from each other; and
bonding a die over the redistribution structure, wherein the die is electrically connected to the first conductive feature, and the heat transfer feature overlaps the die in a direction perpendicular to a top surface of the dielectric layers.

16. The method as claimed in claim 15, further comprising forming a second conductive feature over the dielectric layers, wherein the second conductive feature connects to the first conductive feature and is separated from the heat transfer feature by the dielectric layers.

17. The method as claimed in claim 15, wherein bonding the die comprises positioning the die over the heat transfer feature.

18. The method as claimed in claim 15, wherein forming the heat transfer feature comprises:
forming a first heat transfer layer;
forming a via connected to the first heat transfer layer; and
forming a second heat transfer layer connected to the via.

19. The method as claimed in claim 18, wherein forming the heat transfer feature further comprises forming a sealing ring connecting the first heat transfer layer and the second heat transfer layer and surrounding the via.

20. The method as claimed in claim 15, wherein the first conductive feature is partially exposed from the dielectric layers, and the heat transfer feature is embedded in the dielectric layers.
